(19) United States
(12) Patent Application Publication
(10) Pub. No.: US 2015/0373867 A1
(43) Pub. Date: Dec. 24, 2015

(54) ELECTRONICS HOUSING

(71) Applicant: Continental Automotive Systems, Inc., Auburn Hills, MI (US)

(72) Inventors: Paulo Cesar Ochoa Reyes, Tlajomulco de (MX); Johnathan Guarneros Jones, Tlajomulco de Zuniga (MX); Irving Uriel Hernandez Orozco, Tlajomulco de Zuniga (MX)

(21) Appl. No.: 14/308,307

(22) Filed: Jun. 18, 2014

(51) Int. Cl. H05K 5/06; B21D 11/10; H05K 5/02; B21D 22/02; H05K 5/04; H05K 5/00

(52) U.S. Cl. CPC H05K 5/061; H05K 5/04; H05K 5/0026; H05K 5/0056; H05K 5/0004; H05K 5/0239; B21D 22/02; B21D 11/10

(57) ABSTRACT

An electronics housing is provided. The electronics housing includes a first enclosure portion, a bending portion unitarily formed with the first enclosure portion, and a second enclosure portion unitarily formed with the bending portion. The bending portion is configured to be bent from an initial position to a final position. The first and second enclosure portions cooperate to define an internal cavity therebetween when the bending portion is in the final position. An engine control unit and a method of forming an engine control unit are also provided.

### FIELD

The present disclosure relates generally to electronics enclosures, and more specifically to an electronics enclosure for use in an automotive powertrain system.

### BACKGROUND

Modern vehicles, such as cars, incorporate electronic systems and controllers into the engine designs. The electronic systems enable proper operation of the engine and other vehicle systems during all operating conditions. Some operating conditions, such as rain or sleet, are hazardous to exposed electronics and can damage or destroy exposed electronics. In order to protect the electronic systems, typical vehicles isolate the electronic components from the environmental hazards by placing the electronics within an electronics housing module.

Electronics housing modules, or enclosures, include a housing body and a cover that seals the housing body. The sealed enclosure protects the electronics that are contained within from external contaminants. The housing body can further include sealed communication ports allowing the electronics module to be connected to sensors or other electric systems within the vehicle.

The housing module is typically formed by die casting an upper part and a lower part, or a housing and a cover. The two parts may then be held together by screws.

### SUMMARY

Disclosed is an electronics housing that is formed of a single housing part and may be stamped as one piece.

In one example, which may be combined with or separate from the other examples provided herein, an electronics housing includes a first enclosure portion, a bending portion unitarily formed with the first enclosure portion, and a second enclosure portion unitarily formed with the bending portion. The bending portion is configured to be bent from an initial position to a final position. The first and second enclosure portions cooperate to define an internal cavity therebetween when the bending portion is in the final position.

In another example, which may be combined with or separate from the other examples provided herein, an engine control unit is provided. The engine control unit includes a housing having a first enclosure portion, a bending portion unitarily formed with the first enclosure portion, and a second enclosure portion unitarily formed with the bending portion. The bending portion is configured to be bent from an initial position to a final position. The first and second enclosure portions cooperate to define an internal cavity therebetween when the bending portion is in the final position. A printed circuit board is disposed in the internal cavity of the housing.

In yet another example, which may be combined with or separate from the other examples provided herein, a method of forming an engine control unit is provided. The method includes stamping a metal housing, the metal housing having a first enclosure portion, a bending portion unitarily formed with the first enclosure portion, and a second enclosure portion unitarily formed with the bending portion. The method also includes bending the bending portion to bring the first and second enclosure portions into contact with each other and to define an internal cavity between the first and second enclosure portions.

In still another example, which may be combined with or separate from the other examples provided herein, a method of forming an engine control unit is provided. The method comprises stamping a metal housing, the metal housing having a first enclosure portion, a bending portion unitarily formed with the first enclosure portion, and a second enclosure portion unitarily formed with the bending portion.

These and other features can be best understood from the following specification and drawings, the following of which is a brief description.

### BRIEF DESCRIPTION OF THE DRAWINGS

The drawings are provided for illustrative purposes only and are not intended to limit the invention, as defined in the claims.

FIG. 1 is a perspective view of an outer side of an electronics housing prior to assembly, in accordance with the principles of the present disclosure;

FIG. 2 is a perspective view of an inner side of the electronics housing of FIG. 1 prior to assembly, according to the principles of the present disclosure;

FIG. 3 is a perspective view of the inner side of the electronics housing of FIGS. 1-2, with the electronics housing bent partially in an intermediate position, in accordance with the principles of the present disclosure;

FIG. 4 is a perspective view of the electronics housing of FIGS. 1-3 in a final position and having a printed circuit board disposed therein, according to the principles of the present disclosure;

FIG. 5 is an assembled perspective view of the electronics housing of FIGS. 1-4, according to the principles of the present disclosure; and

FIG. 6 is a block diagram illustrating a method of forming an engine control unit, in accordance with the principles of the present disclosure.

### DESCRIPTION

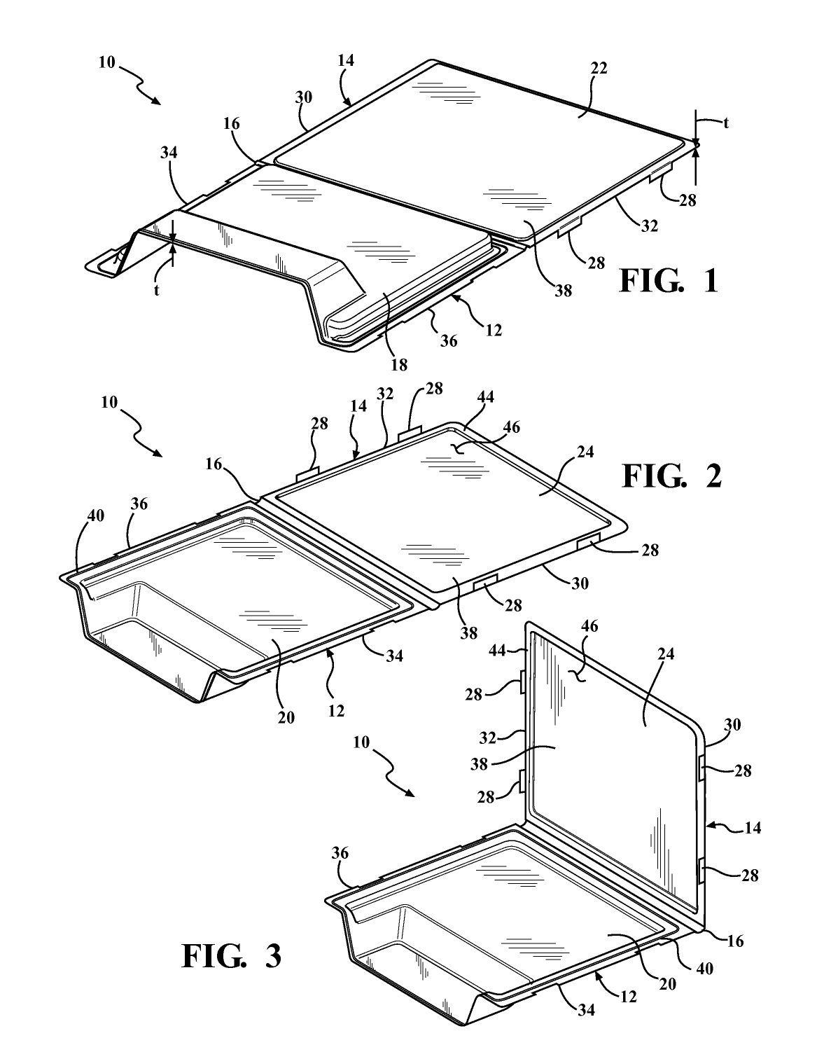

FIGS. 1-2 illustrate a perspective view of an electronics housing, which is generally designated at 10. The electronics housing 10 has a first enclosure portion 12, which may be a main body portion, by way of example, and a second enclosure portion 14, which may be a lid to the main body portion. A bending portion 16 connects the first enclosure portion 12 to the second enclosure portion 14. The bending portion 16 is shown in an initial position, wherein the bending portion 16 is unbent. The bending portion 16 is unitarily formed with the first enclosure portion 12, and the bending portion 16 is also unitarily formed with the second enclosure portion 14. Thus, the housing 10 is unitarily formed from a single piece of material.

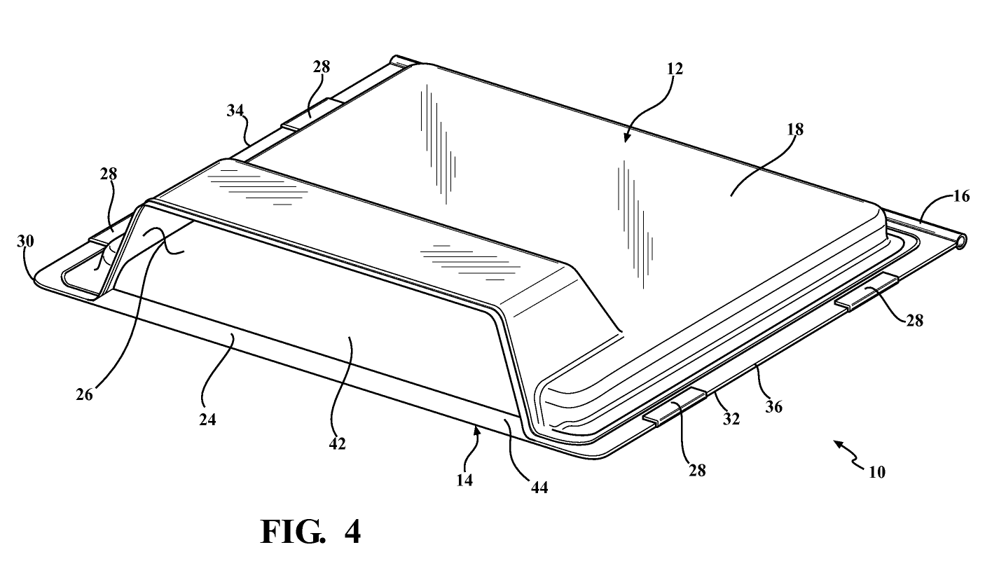

The first enclosure portion 12 has an outer side 18 and an inner side 20. The second enclosure portion 14 has an outer side 22 and an inner side 24. The bending portion 16 is configured to be bent from an initial position (unbent position), as shown in FIGS. 1-2 to a final position (fully bent position), as shown in FIG. 4. FIG. 3 shows the bending portion 16 in an intermediate position between the initial and final positions, as the bending portion 16 is bent from the initial position to the final position.

Accordingly, the electronics housing 10 may be formed as a single part from a stamped material. For example, the electronics housing 10 may be stamped from steel or aluminum. In some variations, the first and second enclosure portions 12, 14 may each have a thickness t in the range of about 0.6 mm to about 0.8 mm.

With reference to FIG. 4, the electronics housing 10 is illustrated with the bending portion 16 in the final position. The bending portion 16 has been bent to bring the inner sides 20, 24 of the first and second enclosure portions 12, 14 together. As such, the first and second enclosure portions 12, 14 cooperate to define an internal cavity 26 therebetween when the bending portion 16 is bent into the final position. The first and second enclosure portions 12, 14 may be sealed together and cooperate to form the inner cavity 26 therebetween.

The electronics housing 10 may include a plurality of tabs 28 that extend from one or both of the first and second enclosure portions 12, 14. In the illustrated example, there are four tabs 28, and each tab 28 extends from an edge 30, 32 of the second enclosure portion 14. However, it should be understood that any number of tabs 28 could be used and the tabs 28 could alternatively or additional extend from edges 34, 36 of the first enclosure portion 12. In the illustrated example, upon the initial creation of the housing 10 as shown in FIG. 1, the tabs 28 are disposed in planes that are perpendicular to the plane of the main body 38 of the second enclosure portion 14, in a first position of the tabs 28. However, it should be understood that the tabs 28 could be original created in another orientation, such as being coplanar with the main body 38.

Referring now to FIG. 4, the housing 10 is shown with the bent portion 16 in the final position. Accordingly, the inner sides 20, 24 of the first and second enclosure portions 12, 14 are facing each other, with the edges 30 and 34 disposed adjacent to each other and the edges 32, 36 disposed adjacent to each other. The edges 30, 34 may be in contact with each other, and the edges 32, 36 may be in contact with each other.

In the final position of the bending portion 16, the tabs 28 are folded over into a second position to hold the first and second enclosure portions 12, 14 together. In other words, the tabs 28 may be bent from the first position (shown in FIGS. 1-3) to the second position (shown in FIG. 4). Thus, the tabs 28 are bent to hold the first and second enclosure portions 12, 14 together. The tabs 28 contact the outer side 18 of the first enclosure portion 12 in the second position of the tabs 28.

A sealant material may be disposed between the first and second enclosure portions 12, 14. In their second positions, the tabs 28 hold the first and second enclosure portions 12, 14 together while the sealant material cures. The sealant material may be disposed in a groove 40 that is formed in the inner side 20 of the first enclosure portion 12, by way of example. The sealant material may be Silicone, by way of example.

Referring to FIG. 4, a printed circuit board 42 may be disposed in the internal cavity 26 of the electronics housing 10. The electronics housing 10 may have geometry to support the printed circuit board 42 therein. For example, the second enclosure portion 14 may form a lip 44 around a pocket 46 for receiving and placing the printed circuit board 42. Thus, the printed circuit board 42 and/or other electronics components may be disposed within the internal cavity 26 of the electronics housing 10. A thermal interface material may be dispensed into the pocket 46 or against one or both of the first and second enclosure portions 12, 14 prior to placing the printed circuit board 42 in the housing 10. The thermal interface material may be formed of any suitable material, such as a Silicone-based or rubber-based material. For example, a suitable thermal interface material may be a Silicone-rubber material sold under the trade name Semicosil. Another suitable thermal interface material may be a thermal gap-filler material, such as an elastomer. A suitable gap-filler material may be an elastomeric material sold by the Berquist company under the product name GF1500. In some variations, the electronics housing 10 and the printed circuit board 42 may form an engine control unit (ECU), wherein the printed circuit board 42 forms part of an engine controller.

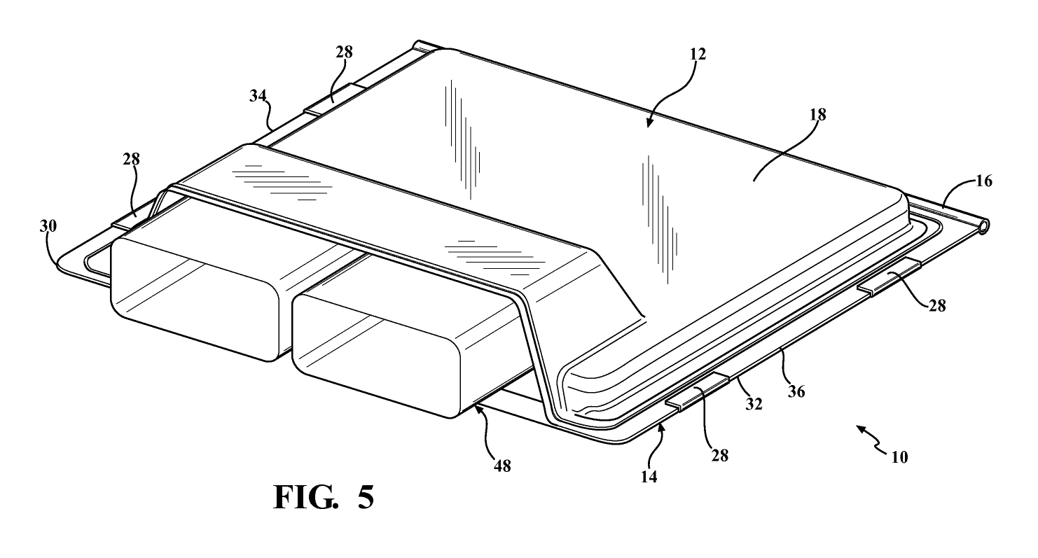

Referring now to FIG. 5, a connector 48 is attached to the printed circuit board 42 for electrically connecting the printed circuit board 42 to outside components. The connector 48 may be attached to the printed circuit board 42 prior to placing the printed circuit board 42 within the electronics housing 10; however, in FIG. 4, the printed circuit board 42 is shown in the internal cavity 26 without the connector 48 for illustrative purposes. The sealant material is configured to seal the internal cavity 26 when the electronics housing 10 is assembled with the connector 48 and printed circuit board 42.

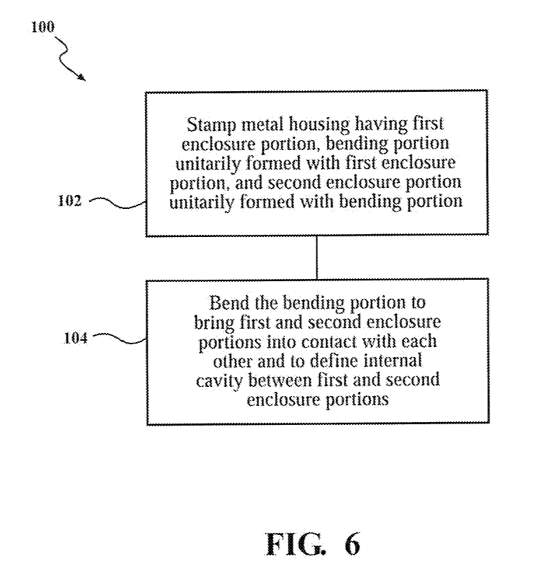

Referring now to FIG. 6, a method for forming an engine control unit is illustrated and generally designated at 100. The method 100 includes a step 102 of stamping a metal housing, the metal housing having a first enclosure portion, a bending portion unitarily formed with the first enclosure portion, and a second enclosure portion unitarily formed with the bending portion. For example, the method 100 may include stamping the electronic housing 10 having the configuration shown in FIGS. 1-5.

The method 100 further includes a step 104 of bending the bending portion to bring the first and second enclosure portions into contact with each other and to define an internal cavity between the first and second enclosure portions. For example, the bending portion may be bent to form an internal cavity as illustrated in FIG. 4.

In some variations, the method 100 may include additional steps, such as disposing a printed circuit board in the internal cavity. For example, the printed circuit board may be disposed in the internal cavity as illustrated in FIG. 4. The method 100 may also include dispensing a thermal interface material against at least one of the first and second enclosure portions. For example, the thermal interface material may be dispensed in the pocket 46 of the second enclosure portion 14. The method 100 may include pressing the printed circuit board against the thermal interface material. In addition, the method 100 may include providing the metal housing with a plurality of tabs extending from one of the first and second enclosure portions, such as the tabs 28 illustrated in FIGS. 1-5. Further, the method 100 may include bending the tabs to hold the first and second enclosure portions together, for example, as shown in FIGS. 4-5. In some variations, the method 100 may include providing a groove in the first enclosure portion and disposing a sealant material in the groove, such as the groove 40 shown in FIGS. 1 and 3.

In some variations, the step 104 of bending the bending portion to bring the first and second enclosure portions into contact with each other and to define an internal cavity between the first and second enclosure portions may be eliminated. For the example, the method 100 may include the step 102 of stamping a metal housing, the metal housing having a first enclosure portion, a bending portion unitarily formed with the first enclosure portion, and a second enclosure portion unitarily formed with the bending portion, with or without the step 104.

In some variations, the method 100 may include locating the stamped metal housing in a fixture and dispensing a sealant, such as a thermal interface material, in the connector area. The method 100 may include putting the PCB with the connector in place and dispensing a sealant material about the perimeter of the housing. The sheet metal housing may then be bent in half and closed, and the tabs may be crimped to maintain the housing in the closed position.

The disclosed electronics enclosure and/or ECU may provide a less expensive and simpler alternative to a die cast two-piece enclosure. The enclosure and method described herein may also simplify the manufacturing process.

It is further understood that any of the above described concepts can be used alone or in combination with any or all of the other above described concepts. Although an embodiment of this invention has been disclosed, a worker of ordinary skill in this art would recognize that certain modifications would come within the scope of this invention. For that reason, the following claims should be studied to determine the true scope and content of this invention.

What is claimed is:

1. An electronics housing comprising:
a first enclosure portion;
a bending portion unitarily formed with the first enclosure portion; and
a second enclosure portion unitarily formed with the bending portion, the bending portion being configured to be bent from an initial position to a final position, the first and second enclosure portions cooperating to define an internal cavity therebetween when the bending portion is in the final position.

2. The electronics housing of claim 1, the electronics housing being formed of a stamped material.

3. The electronics housing of claim 2, wherein the stamped material is one of steel and aluminum.

4. The electronics housing of claim 2, further comprising a plurality of tabs extending from at least one of the first and second enclosure portions, each tab being configured to be bent to hold the first and second enclosure portions together.

5. The electronics housing of claim 2, further comprising a sealant material disposed between the first and second enclosure portions, the sealant material being configured to seal the internal cavity when the electronics housing is assembled with a connector.

6. The electronics enclosure of claim 5, the first enclosure portion forming a groove therein, the sealant material being disposed in the groove.

7. The electronics enclosure of claim 2, further comprising a printed circuit board disposed in the internal cavity.

8. The electronics enclosure of claim 2, wherein the first and second enclosure portions each have a thickness in the range of about 0.6 mm to about 0.8 mm.

9. An engine control unit comprising:
a housing having a first enclosure portion, a bending portion unitarily formed with the first enclosure portion, and a second enclosure portion unitarily formed with the bending portion, the bending portion being configured to be bent from an initial position to a final position, the first and second enclosure portions cooperating to define an internal cavity therebetween when the bending portion is in the final position; and
a printed circuit board disposed in the internal cavity of the housing.

10. The engine control unit of claim 9, the housing being formed of a stamped material.

11. The engine control unit of claim 10, wherein the stamped material is one of steel and aluminum.

12. The engine control unit of claim 11, further comprising a plurality of tabs extending from at least one of the first and second enclosure portions, each tab being configured to be bent to hold the first and second enclosure portions together.

13. The engine control unit of claim 12, further comprising a connector assembled with the housing, the engine control unit further comprising a sealant material disposed between the first and second enclosure portions, the sealant material being configured to seal the internal cavity.

14. The engine control unit of claim 13, wherein the first enclosure portion has a groove formed therein, the sealant material being disposed in the groove.

15. A method of forming an engine control unit, the method comprising:
stamping a metal housing, the metal housing having a first enclosure portion, a bending portion unitarily formed with the first enclosure portion, and a second enclosure portion unitarily formed with the bending portion; and
bending the bending portion to bring the first and second enclosure portions into contact with each other and to define an internal cavity between the first and second enclosure portions.

16. The method of claim 15, further comprising disposing a printed circuit board within the internal cavity.

17. The method of claim 16, further comprising dispensing a thermal interface material against at least one of the first and second enclosure portions, the method further comprising pressing the printed circuit board against the thermal interface material.

18. The method of claim 17, further comprising providing the metal housing with a plurality of tabs extending from at least one of the first and second enclosure portions, the method further comprising bending each tab to hold the first and second enclosure portions together.

19. The method of claim 18, further comprising providing a groove in the first enclosure portion, the method further comprising disposing a sealant material in the groove.

20. A method of forming an engine control unit, the method comprising stamping a metal housing, the metal housing having a first enclosure portion, a bending portion unitarily formed with the first enclosure portion, and a second enclosure portion unitarily formed with the bending portion.
